(19) United States
(12) Patent Application Publication
(10) Pub. No.: US 2011/0017296 A1
(43) Pub. Date: Jan. 27, 2011

(54) SOLAR CELL HAVING LIGHT CONDENSING DEVICE AND LARGER EFFECTIVE AREA AND THE METHOD OF THE SAME

(76) Inventors: Kuo-Ching Chiang, Taipei County (TW); Hung-Huei Tseng, Hsinchu City (TW)

Correspondence Address: Muncy, Geissler, Olds & Lowe, PLLC, 4000 Legato Road, Suite 310, FAIRFAX, VA, 22033, US

(21) Appl. No.: 12/842,506

(22) Filed: Jul. 23, 2010

(30) Foreign Application Priority Data
Jul. 23, 2009 (TW) 098124927

(51) Int. Cl. H01L 31/0232; H01L 31/0256; H01L 31/02

(52) U.S. Cl. 136/259; 136/262; 136/252

(57) ABSTRACT

The present invention discloses a solar cell having light condensing device such as micro lens. The solar cell includes a substrate, a solar energy converting layer is formed over the substrate, and a plurality of light condensing device is formed over the solar energy converting layer. The material of the light condensing device includes organic material including photo-resist or inorganic material including silicon dioxide or silicon nitride.

### FIELD OF THE INVENTION

The present invention is generally related to a solar cell and the method of the same, and more particularly to a solar cell having light condensing device, such as micro lens, and larger effective area

### BACKGROUND OF THE INVENTION

Because of global warming, the energy becomes a serious social problem and the energy saving becomes an important policy gradually. A solar cell could convert solar energy into electricity to use resources effectively and prevent environmental pollution, therefore, solar cell becomes an energy saving indicator. Common solar cells are produced on a silicon wafer. Compared polysilicon and amorphous silicon solar cells with monocrystalline silicon solar cells, the cost of polysilicon and amorphous silicon solar cells is lower and the manufacturing process of polysilicon and amorphous silicon solar cells is easier. In recently years, solar cells made of organic materials, such as polymer, are attached importance to by the academic and industry. Polymer solar cells are made of the material with similar characteristics of plastic, which has light weight and excellent flexibility and has crash tolerance, impact tolerance and low cost.

In addition, polymer solar cells have progressed in structure from single layer structure, heterojunction structure to bulk heterojunction structure. However, the efficiency of solar cell energy converting power is still limited. For the reason that, there are several sub-solar cells stacked in series/parallel to produce the solar cell device in prior art, but the solar cell made by stacking up the sub-solar cells has a considerable thickness and the efficiency of solar cell energy converting power is not as expected.

Consequently, an effective mean to improve the efficiency of solar cell energy converting power is needed.

### SUMMARY OF THE INVENTION

The purpose of the present invention is to provide a solar cell having plural light condensing devices and the method of the same.

Another purpose of the present invention is to provide a solar cell having larger effective area and the method of the same.

Another purpose of the present invention is to provide a solar cell having a transparent electrode to reduce light-shading rate.

A device having plural light condensing, such as a solar cell of micro lens, which comprises: a first type semiconductive layer; a second type semiconductive layer, which is coupled with the first type semiconductive layer; a plurality of micro light condensing devices, which is formed on the second type semiconductive layer. The material of a plurality of micro light condensing devices includes organic material, such as photo-resist, and inorganic material, such as silicon nitride or silicon oxide. A transparent electrode is configured on the second type semiconductive layer.

A solar cell having high effective area, which comprises: a first type semiconductive layer; a second type semiconductive layer, which is coupled with the first type semiconductive layer; wherein the second type semiconductive layer includes a concave structure to increase the light irradiation area. The area is increased by 1/cos Θ (or secΘ) times or π/2 times area to receive the light irradiation, and the Θ is defined as an included angle between the area and the second type semiconductive layer. The Θ is less than 90 degrees and greater than 10 degrees. The concave structure includes periodic sloped sidewall trenches and periodic trenches of which section is triangle, arc shaped, wave shaped, wherein the concave structure is made by optical lithography technology or mechanical mold imprinting process.

A solar cell, which comprises: a first type semiconductive layer; a second type semiconductive layer, which is coupled with the first type semiconductive layer; a transparent electrode is configured in or on the second type semiconductive layer to reduce the light-shading rate. The material of the transparent electrode includes metal oxides and the metal is selected from one or more of aurum, silver, indium, gallium, aluminum, tin, germanium, antimony, zinc, platinum and palladium. The material of the transparent electrode includes conductive polymer, conductive adhesive, silver-aluminum paste, carbon nanotubes.

The present invention may be understood by some preferred embodiments and detailed descriptions in the specification and the attached drawings below.

### BRIEF DESCRIPTION OF THE DRAWINGS

The identical reference numbers in the drawings refer to the same components in the present invention. However, it should be appreciated that all the preferred embodiments of the invention are only for illustrating but not for limiting the scope of the Claims and wherein:

FIG. 1 illustrates a schematic diagram of forming bumps in accordance with one embodiment of the present invention;

FIG. 2 illustrates a schematic diagram of forming light condensing device in accordance with one embodiment of the present invention;

FIG. 3 illustrates a schematic diagram of forming concave in accordance with one embodiment of the present invention;

FIG. 4 illustrates a cross sectional views of forming concave in accordance with one embodiment of the present invention;

FIG. 5 illustrates a cross sectional views of forming concave in accordance with one embodiment of the present invention;

FIG. 6 illustrates a cross sectional views of forming concave in accordance with one embodiment of the present invention;

FIG. 7 illustrates a schematic diagram of the time before the imprinting by molds in accordance with one embodiment of the present invention;

FIG. 8 illustrates a schematic diagram of the time to imprint by molds in accordance with one embodiment of the present invention;

FIG. 9 illustrates a schematic diagram of the roller molds imprinting in accordance with one embodiment of the present invention

### DETAILED DESCRIPTION OF THE PREFERRED EMBODIMENT

The invention will now be described with the preferred embodiments and aspects and these descriptions interpret structure and procedures of the invention only for illustrating but not for limiting the Claims of the invention. Therefore, except the preferred embodiments in the specification, the present invention may also be widely used in other embodiments.

The present invention is applicable to various solar cells, for example, PN type, PIN type, homojunction type, back surface field (BSF) type and lamination (stacked) type. The present invention is also applicable to junction, diffusion, monocrystal growth and ion implantation. Diffusion could use POCl₃ and PH₃ as n-type dopants. If adopting polycrystalline silicon process, due to high-speed manufacturing process is likely to generate defects at the outside of the grain boundary, hydrogen could be lead in process. If adopting amorphous silicon process, then SiH₄ could lead in process by Chemical Vapor Deposition (CVD) or the film could be formed by sputtering. To film solar cell, it could also adopt roll to roll process.

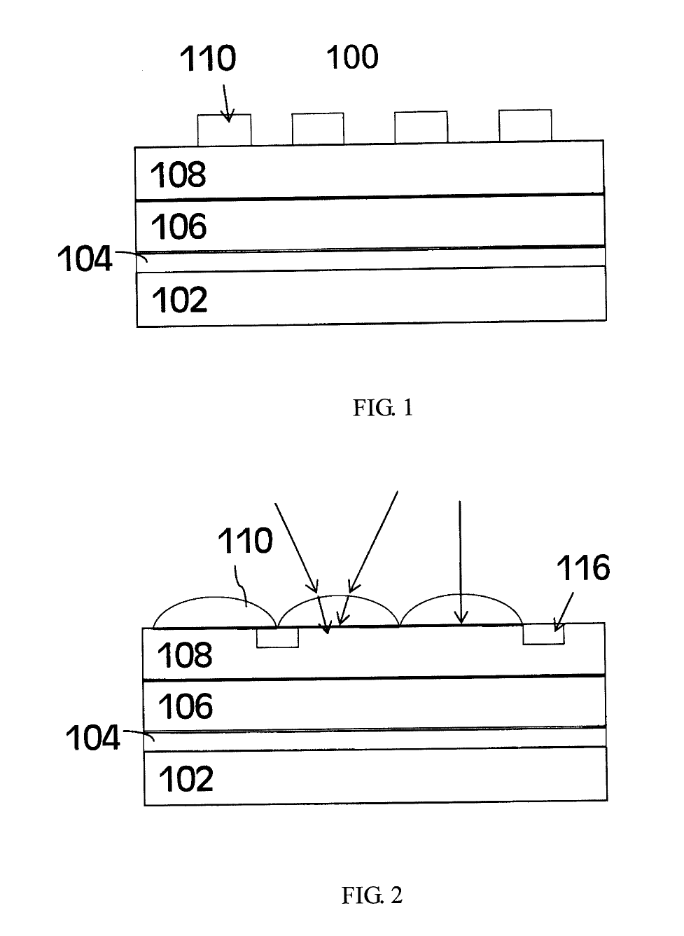

Please refer to FIG. 1, to provide a solar cell 100, the solar cell 100 comprises a substrate 102, the substrate 102 could be any substrates applied to solar cells which includes a glass substrate, silicon, germanium, quartz, ceramic or a flexible substrate and so on. In this embodiment, the first electrode 104 is configured on the substrate 102 and the electrode could be metal, alloy, indium tin oxide (ITO), conductive polymer, conductive adhesive, silver-aluminum paste, carbon nanotubes.

A solar cell converting layer includes a first type semiconductive layer 106 and a second type semiconductive layer 108. It includes a photosensitive dye if it is a dye sensitized solar cell (DSSC). Take a solid-state solar cell as an example, a first type semiconductive layer 106, such as p-type monocrystalline, polycrystalline or amorphous silicon layer (but not limited) or compound semiconductor (such as GaAs, InP, but no limited), is configured on the first electrode 104. After that, a second type semiconductive layer 108, such as n-type monocrystalline, polycrystalline or amorphous silicon layer (but not limited) or compound semiconductor (such as GaAs, InP, but no limited), is configured on the first type semiconductive layer 106 to form p-n junction. The semiconductor layer could be made by ion implantation method or high temperature diffusion method. Doped silicon layer is formed by using phosphorus and the source of the phosphorus is dissociated from the gas of PH₃. If it is PIN type, it includes an insulation layer between the p-n junctions, for instance, a thin oxide layer could act as the insulation layer for PIN structure. In one better embodiment, the oxide layer is made by silicon oxide which is formed within an oxygen steam ambient at 800° C.-1100° C. As the same reason, the oxide layer is also formed by suitable chemical compound of oxides and process. For example, the oxide layer could be formed of silicon dioxide by chemical vapor deposition method which used tetraethyl orthosilicate (TEOS) at the temperature of 600° C.-800° C. and the vapor of about 0.1-10 torr.

The characteristic of the present invention is that the solar cell includes a plurality of micro light condensing devices 110, such as micro lens are distributed on the second type semiconductive layer 108 to gather sun light from each direction directly or indirectly and lead into the second type semiconductive layer 108 to increase the photon number into the cells.

For example, the plural micro light condensing devices includes a plurality of micro lens. The micro light condensing devices 110 could be made by forming a plurality of bumps which are material of micro lens over the second type semiconductive layer 108 by optical lithography process, spray coating, printing or screen printing.

To optical lithography process as an example, a positive photoresist is coated with a thickness of about 1000 nm at the first, and the photoresist is then exposed and developed by optical lithography technology to form the width of about 2000 nm pattern. Subsequently, the pattern is treated through heat reflow with 30-60 seconds at the temperature of 130° C.-200° C. Based on the surface tension, the shape of the pattern transforms into curved surface shape or hemispherical shape, therefore, the pattern has the capacity of light condensing and causes the solar converting layer to generate more photoelectrons, as shown in FIG. 2.

According to the plural light condensing devices could configure correspondingly about majority of solar cells, the light condensing devices could enhance the absorption of light. The micro lens material includes glass, liquid glass, organic materials (such as photoresist), and inorganic materials (such as silicon nitride or silicon oxide). Using optical lithography, mask, or screen printing pitch could control the size and number of micro lens. The plural light condensing devices 110 may be directly or indirectly formed on the second type semiconductive layer 108.

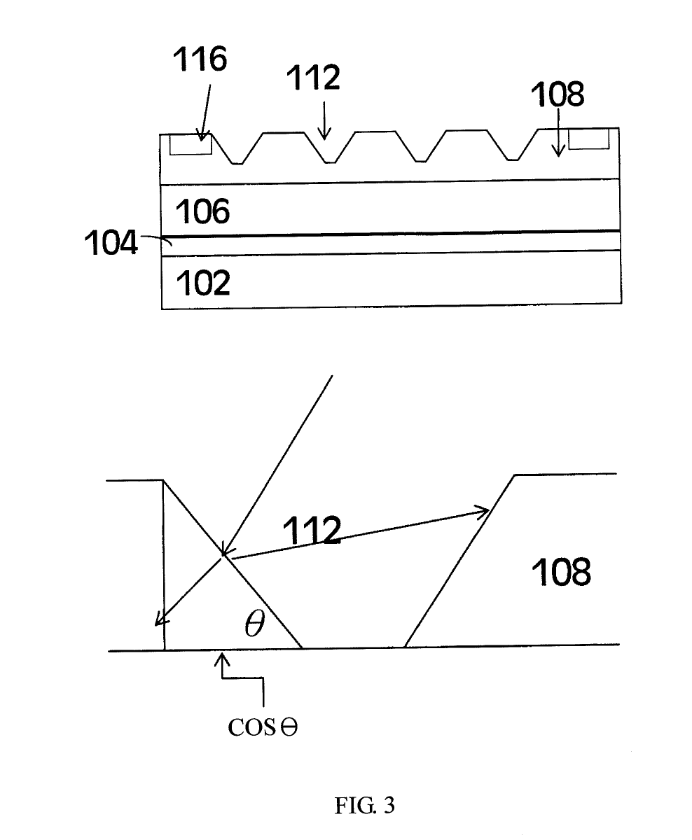

In another embodiment, the present invention provides high effective area, for example, by the concave structure 112 on the second type semiconductive layer 108. The concave structure 112 could increase surface area to elevate the light irradiation area and have advantages of increasing the reception of light, with reference to FIG. 3. The area is increased by 1/cos Θ (or secΘ) times which is the function of theta (Θ). The Θ is defined as an included angle between the sidewall of the concave structure 112 and the surface (horizontal surface) of the second type semiconductive layer 108. The suggested degree is greater than 10 degrees and less than 90 degrees, preferably 30-60 degrees. As shown is figure, if the angle designed appropriately, it could cause the secondary incidence of light to enhance the reception of light. It is worth noting that the concave structure is different from the texture structure which is to reduce reflectivity and the applications of both are different. The texture structure is usually irregular, random and unregular and the concave structure 112 is at least with regional rule or regional periodic patterns.

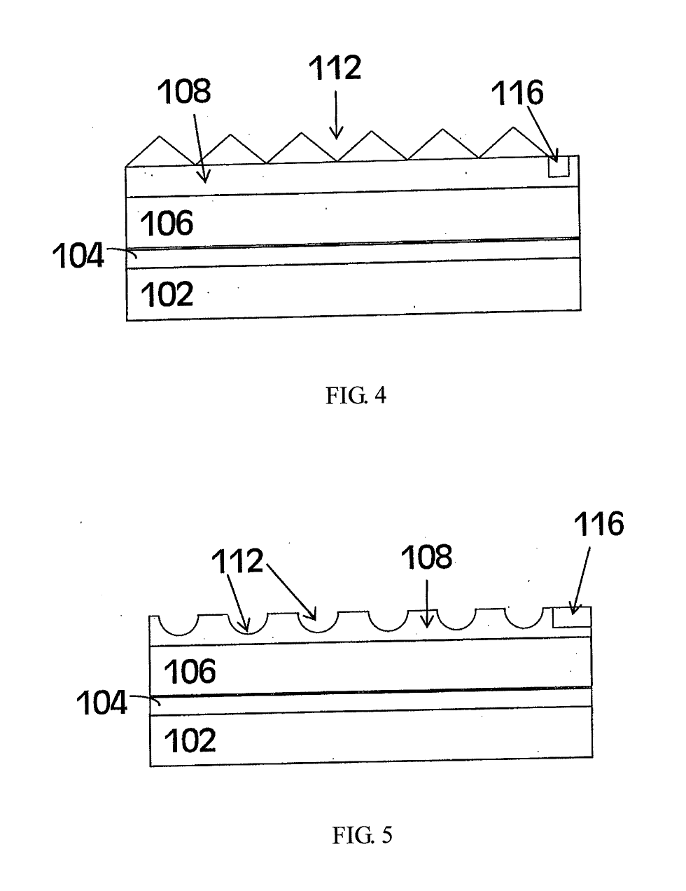

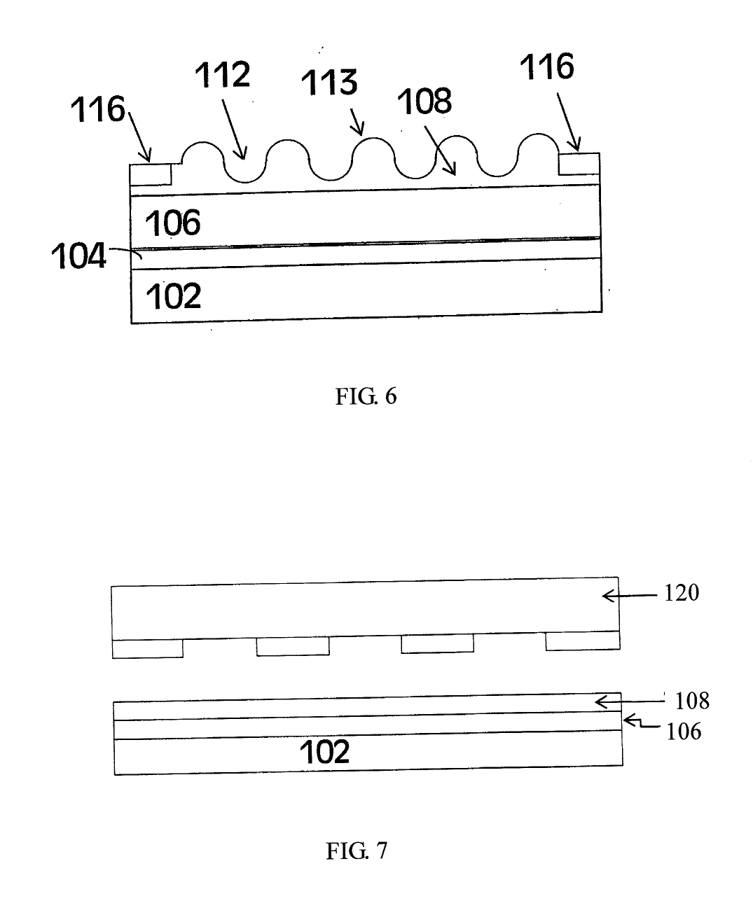

In one embodiment, the second type semiconductive layer 108 has thickness of about 1.5-3 micrometer and the depth of the concave structure is about a quarter to three fourths of the second type semiconductive layer 108 thickness. FIG. 4 and FIG. 5 respectively illustrate different cross sectional views of the concave structure 112. FIG. 4 illustrates the section of the concave which is a triangular structure and FIG. 5 illustrates the section of the concave which is an arc shaped structure. The structures could reduce the shadow or shading effect to increase received light and the secondary incidence of light. The area is increased by πr/2r (or π/2) times and r is defined the radius of the semicircle. FIG. 6 illustrates the section of the concave which is the wave shape structure (which is a hybrid structure of convex 113 and concave 112) which could gain further area than which of FIG. 5. To the ordinary skill in the art, the section of the concave 112 of above mentioned are illustrated for examples but not for limiting and the ordinary skill in the art may make any modifications according to their demands. The concave 112 could be made by photo-lithography process or mold imprinting process (micron print, by mechanical force). The wave shape could be form by using lateral etching to etch the upper portion after the concave formed by above mentioned method. Then, there may form a similar wave structure.

In above mentioned embodiment, the second electrode 116 is configured on the solar cell, which could be configured on or in the second type semiconductive layer 108. The second electrode 116 is generally used imprinting process or photo-lithography process to make a trenches, and then the second electrode material is refilled into the trenches. After planarization, the second electrode could be embedded in the second type semiconductive layer 108. Conventional electrode is used metal or alloy, however, the electrodes would cover parts of the second type conductive layer 108 areas and reduce the reception of light. The embodiment employs the transparent electrode and the material of the transparent electrode includes metal oxides which are selected from one or more of aurum, silver, indium, gallium, aluminum, tin, germanium, antimony, zinc, platinum and palladium. The material of the second electrode made of ITO and ZnO is preferred and it also could include the conductive polymer, conductive adhesive, silver-aluminum paste, carbon nanotubes, or the combination thereof.

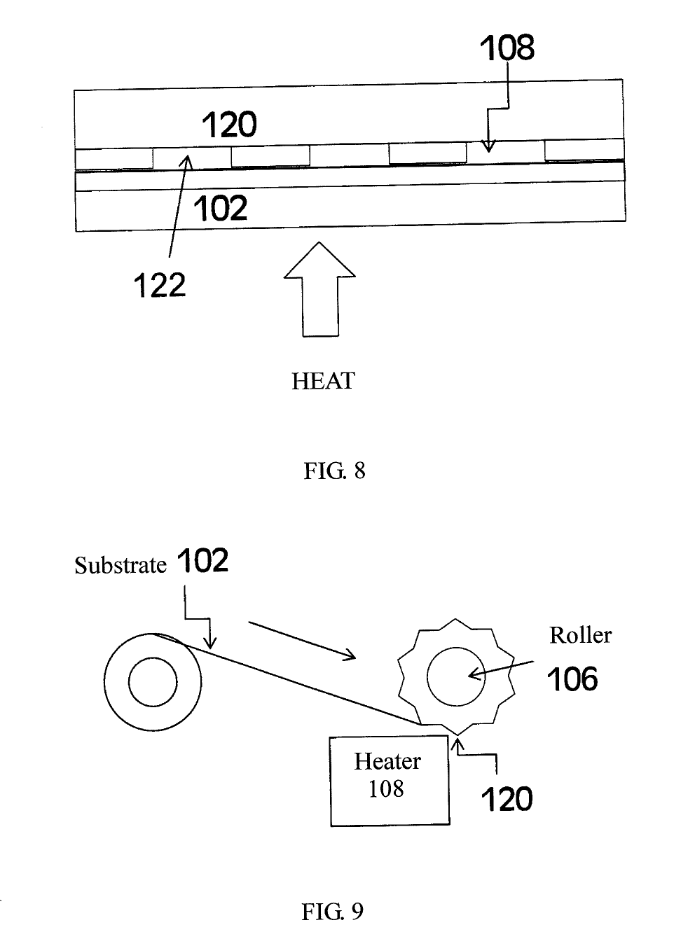

The molds imprinting technology employs the molds 120 having specific pattern to imprint on the semiconductive layer 108 at the suitable temperature and pressure, as shown in FIG. 7. After releasing molds and form the imprinting pattern on the layer, the imprinted metal is processed with the surface heat treatment to make micrometer or nanometer imprinting 122, as shown in FIG. 8. If using flexible substrate, imprinting process could be implemented by roll-to-roll process, as shown in FIG. 9. The substrate is drived to move by roll-to-roll device and the other end of roll connects to mold to make the film move and be compression molded on the flexible substrate. The roll-to-roll imprinting process would increase the production efficiency. The roll-to-roll device could use the driving device, such as motor, to drive the roll-to-roll device and to make the flexible substrate move. As shown by the direction of arrow in figure, the substrate could be rolled from the end to the other end. In this process, the substrate is move and the rotating speed of the roll could be controlled to advantage to control the motion rate.

Through the detailed description above, the spirit and features should be thoroughly understood by the ordinary skill in the art. However, the details in the embodiments are only for examples and explanation. The ordinary skill in the art may make any modifications according to the teaching and suggestion of the embodiments of the present invention, for meeting the various situations, and they should be viewed as in the scope of the present invention without departing the spirit of the present invention. The scope of the present invention should be defined by the following claims and the equivalents.

What is claimed is:

1. A solar cell having light condensing devices, comprising:
a substrate;
a solar converting layer, which is configured on said substrate; and
a plurality of light condensing devices, which is configured over said solar converting layer.

2. A solar cell having light condensing devices according to claim 1, wherein said light condensing devices includes photoresist.

3. A solar cell having light condensing devices according to claim 1, wherein said light condensing devices includes organic material or inorganic material.

4. A solar cell having light condensing devices according to claim 1, wherein said light condensing devices includes silicon oxide or silicon nitride.

5. A solar cell having light condensing devices according to claim 1, wherein said solar converting layer includes a first type semiconductive layer.

6. A solar cell having light condensing devices according to claim 1, wherein said solar converting layer includes a second type semiconductive layer.

7. A solar cell having light condensing devices according to claim 6, wherein said second type semiconductive layer includes a concave structure.

8. A solar cell having light condensing devices according to claim 7, wherein said concave structure includes a plurality of periodic pattern.

9. A solar cell having larger effective area, comprising:
a first type semiconductive layer; and
a second type semiconductive layer, which is coupled with said first type semiconductive layer;
wherein said second type semiconductive layer includes a concave structure to increase light irradiation area.

10. A solar cell having larger effective area according to claim 9, wherein said increased light irradiation area is 1/cos Θ (or secΘ) times or π/2 times light irradiation area and said Θ is defined as an included angle between said light irradiation area and said second type semiconductive layer.

11. A solar cell having larger effective area according to claim 10, wherein said Θ is less than 90 degrees and greater than 10 degrees.

12. A solar cell having larger effective area according to claim 9, wherein said concave structure includes periodic trenches and said trenches includes an inclined sidewall.

13. A solar cell having larger effective area according to claim 9, wherein said concave structure includes a periodic triangular cross section.

14. A solar cell having larger effective area according to claim 9, wherein said concave structure includes a periodic arc shaped or wave shaped cross section.

15. A solar cell having larger effective area according to claim 9, wherein said concave structure is made by photo lithography etching process or mechanical imprinting process.

16. A solar cell having larger effective area according to claim 9, further comprising a transparent electrode, which is configured on said second type semiconductive layer.

17. A solar cell having larger effective area according to claim 16, wherein the material of said transparent electrode includes metal oxides and the metal is selected from one or more of aurum, silver, indium, gallium, aluminum, tin, germanium, antimony, zinc, platinum and palladium.

18. A solar cell having larger effective area according to claim 16, wherein the material of said transparent electrode includes conductive polymer, conductive adhesive, silver-aluminum paste, or carbon nanotube.

19. A solar cell having larger effective area according to claim 16, wherein said transparent electrode is at least configured on an incident light plane.

20. A solar cell, comprising:
a first type semiconductive layer; and
a second type semiconductive layer, which is coupled with said first type semiconductive layer; and
a transparent electrode, which is configured on or in said second type semiconductive layer to increase the light irradiation area.

21. A solar cell according to claim 20, wherein the material of said transparent electrode includes metal oxides and the metal is selected from one or more of aurum, silver, indium, gallium, aluminum, tin, germanium, antimony, zinc, platinum and palladium.

22. A solar cell according to claim 20, wherein said transparent electrode includes conductive polymer, conductive adhesive, silver-aluminum paste, or carbon nanotube.
